(19) United States
(12) Patent Application Publication
(10) Pub. No.: US 2026/0173784 A1
(43) Pub. Date: Jun. 18, 2026

(54) WAFER PROCESSING APPARATUS AND WAFER PROCESSING METHOD

(71) Applicant: DISCO CORPORATION, Tokyo (JP)

(72) Inventor: Akira MIZUTANI, Tokyo (JP)

(21) Appl. No.: 19/388,022

(22) Filed: Nov. 13, 2025

(30) Foreign Application Priority Data
Dec. 12, 2024 (JP) 2024-217217

(51) Int. Cl. H10P 34/42; H10P 52/00; H10P 72/00

(52) U.S. Cl. CPC H10P 34/42; H10P 52/00; H10P 72/0402; H10P 72/0428

(57) ABSTRACT

A wafer processing apparatus includes a holding table that holds a second wafer of the bonded wafer; a laser beam applying unit that forms a ring-shaped modified layer by positioning a condensing point of a laser beam on an inner side adjacent to the chamfered portion, formed on an outer periphery of the first wafer of the bonded wafer held on the holding table, and applying the laser beam; and a fluid supplying unit that supplies fluid weakening a bonding force to an interface of the chamfered portion in which the first wafer and the second wafer are bonded. The fluid supplying unit includes a liquid storage tank, into which the chamfered portion of the bonded wafer is dipped, at an outer periphery of the holding table, such that an upper face of the first wafer is exposed out of the fluid.

### BACKGROUND

### 1. Technical Field

The present disclosure relates to a wafer processing apparatus and a wafer processing method for processing a bonded wafer, in which a first wafer and a second wafer are bonded.

### 2. Description of the Related Art

A wafer, on the surface of which a plurality of devices, e.g. ICs, LSIs, are formed by being divided along division lines, is, first, formed to a predetermined thickness by grinding the rear face thereof. Then this wafer is divided into individual device chips by a dicing apparatus and a laser processing apparatus, and is used for such electronic device as a mobile phone and a personal computer.

The outer periphery of the wafer is chamfered, hence this chamfered portion becomes a sharp knife edge if the rear surface of the wafer is ground. This knife edge causes, for example, problem of cracking generated from the knife edge, which extends inside the wafer, thereby damaging the device, or a problem of causing injuries to an operator who is handling the wafer. Therefore, a technique to remove the chamfered portion of the wafer has been proposed (see JP 2020-088187 A).

### SUMMARY

However the technique of bonding the first wafer and the second wafer and then grinding the rear face of the first wafer to implement a desired thickness, to improve the functions of the devices, has a problem, that is, removing the chamfered portion from the first wafer is relatively difficult.

In other words, the bonding force of the wafers bonded by siloxane bonds or the like is so strong that even if a modified layer is formed inside the first wafer by positioning a condensing point of a laser beam, which has a wavelength that is transmissive to the wafer, on the inner side adjacent to the chamfered portion, and then applying the laser beam thereto, it is difficult to remove the chamfered portion. Further, in the case of removing the region of a chamfered portion from the first wafer by cutting the region using a cutting blade, there is a problem in that the second wafer may be scratched.

With the foregoing in view, a main technical object of the present disclosure is to provide, in a case where processing is performed on a bonded wafer in which a first wafer and a second wafer are bonded, a wafer processing apparatus and a wafer processing method to solve the problem of removing the chamfered portion, which is difficult to be removed, even if a modified layer is formed by positioning a condensing point of a laser beam, which has a wavelength that is transmissive to the first wafer, on the inner side adjacent to the chamfered portion of the first wafer, and then applying the laser beam.

To solve the above problem, the present disclosure provides a wafer processing apparatus performing processing on a bonded wafer in which a first wafer and a second wafer are bonded. The wafer processing apparatus includes: a holding table that holds the second wafer of the bonded wafer; a laser beam applying unit that forms a ring-shaped modified layer by positioning a condensing point of a laser beam on an inner side adjacent to a chamfered portion, which is formed on an outer periphery of the first wafer of the bonded wafer held on the holding table, and applying the laser beam; and a fluid supplying unit that supplies fluid weakening a bonding force to an interface of the chambered portion in which the first wafer and the second wafer are bonded. The fluid supplying unit includes a liquid storage tank, into which the chamfered portion of the bonded wafer is dipped, at an outer periphery of the holding table, such that an upper face of the first wafer is exposed out of the fluid.

In the case of applying the laser beam in a state where the chamfered portion of the bonded wafer is dipped in the liquid storage tank of the fluid supplying unit, the upper face of the first wafer is exposed out of the fluid, it is preferable that a fluid removal unit, that removes the fluid adhering to the upper face of the first wafer, is disposed. It is also preferable that the fluid removal unit removes the fluid from the upper face of the first wafer by injecting gas from a nozzle to an applying position of the laser beam. It is also preferable that a chamfered portion removal unit configured to remove a chamfered portion from the outer periphery of the first wafer in which the modified layer is formed is disposed. Further, it is preferable that the first wafer and the second wafer are bonded by siloxane bonds of Si-O-Si, the fluid to weaken the bonding force contains at least one of water and ammonia, and the bonding force at the interface is weakened by the function of the fluid, with the bonding of Si-O-Si changing into bonding of Si-OH-OH-Si.

The present disclosure also provides a wafer processing method to perform processing on a bonded wafer in which a first wafer and a second wafer are bonded. The wafer processing method includes: preparing the abovementioned wafer processing apparatus; holding the second wafer of the bonded wafer on a holding table of the wafer processing apparatus; and supplying fluid weakening a bonding force to an interface of a chamfered portion, in which the first wafer and the second wafer are bonded, of the bonded wafer held on the holding table by using a fluid supplying unit of the wafer processing apparatus. In the supplying fluid, the chamfered portion of the bonded wafer is dipped into a liquid storage tank disposed at the outer periphery of the holding table such that the fluid weakening the bonding force at the interface of the chamfered portion is supplied and an upper face of the first wafer is exposed out of the fluid.

The wafer processing apparatus of the present disclosure is a wafer processing apparatus performing processing on a bonded wafer in which a first wafer and a second wafer are bonded. The wafer processing apparatus includes: a holding table that holds the second wafer of the bonded wafer; a laser beam applying unit that forms a ring-shaped modified layer by positioning a condensing point of a laser beam on an inner side adjacent to a chamfered portion, which is formed at an outer periphery of the first wafer of the bonded wafer held on the holding table, and applying the laser beam; and a fluid supplying unit that supplies fluid weakening a bonding force to an interface of the chamfered portion in which the first wafer and the second wafer are bonded. The fluid supplying unit includes a liquid storage tank, into which the chamfered portion of the bonded wafer is dipped, at an outer periphery of the holding table, such that the upper face of the first wafer is exposed out of the fluid. Therefore, the bonding force, in a region corresponding to the chamfered portion at the interface of the bonded wafer, is weakened, and the chamfered portion of the first wafer can be easily removed, starting from the modified layer formed in a ring shape. This solves the problem of the difficulty in removing a chamfered portion. Further, it is unnecessary to use a cutting blade to remove the chamfered portion, hence the problem of scratching the second wafer, to which the first wafer is bonded, is also solved.

The wafer processing method of the present disclosure is a wafer processing method to perform processing on a bonded wafer in which a first wafer and a second wafer are bonded. The wafer processing method includes: preparing the abovementioned wafer processing apparatus; holding the second wafer of the bonded wafer on a holding table of the wafer processing apparatus; and supplying fluid weakening a bonding force to an interface of a chamfered portion, in which the first wafer and the second wafer are bonded, of the bonded wafer held on the holding table by using a fluid supplying unit of the wafer processing apparatus. In the supplying fluid, the chamfered portion of the bonded wafer is dipped into a liquid storage tank disposed on an outer periphery of the holding table such that the fluid weakening the bonding force at the interface of the chamfered portion is supplied and an upper face of the first wafer is exposed out of the fluid. Therefore, the bonding force, in a region corresponding to the chamfered portion at the interface of the bonded wafer, is weakened, and the chamfered portion of the first wafer can be easily removed, starting from the modified layer formed in a ring shape. This solves the problem in the difficulty of removing the chamfered portion. Further, it is unnecessary to use a cutting blade to remove the chamfered portion, hence the problem of scratching the second wafer, to which the first wafer is bonded, is also solved.

### BRIEF DESCRIPTION OF THE DRAWINGS

FIG. 1 is a perspective view of a bonded wafer that is processed by a processing apparatus of this embodiment;

FIG. 2 is a general perspective view of a laser processing apparatus of this embodiment;

FIG. 3A is an enlarged perspective view of a fluid supplying unit disposed on the laser processing apparatus illustrated in FIG. 2, and FIG. 3B is a partially enlarged cross-sectional view of the fluid supplying unit illustrated in FIG. 3A;

FIG. 4A is a perspective view of a state where the fluid supplying unit illustrated in FIG. 3 supplies fluid to an interface of the bonded wafer, and FIG. 4B is a partially enlarged cross-sectional view of the state illustrated in FIG. 4A;

FIG. 5 is a plan view depicting radial modified layer formed on a first wafer;

FIG. 6 is a perspective view depicting a state where a chamfered portion is removed from the outer periphery of the first wafer;

FIG. 7A is an enlarged perspective view of a motor and a chamfered portion removing portion of a chamfered portion removal unit attached to the laser processing apparatus illustrated in FIG. 2, FIG. 7B is a perspective view of the chamfered portion removing portion illustrated in FIG. 7A, viewed obliquely from the lower side, and FIG. 7C is a conceptual diagram depicting a state where the chamfered portion is removed by the chamfered portion removal unit;

FIG. 8 is a perspective view depicting a state where grinding processing is performed for a bonded wafer after the chamfered portion is removed; and

FIG. 9A is a perspective view depicting a state where grinding processing is performed to remove the chamfered portion, and FIG. 9B is a perspective view depicting a state where grinding processing is performed for the bonded wafer after the chamfered portion is removed.

### DESCRIPTION OF THE PREFERRED EMBODIMENTS

Embodiments of a wafer processing apparatus and a wafer processing method, which are configured based on the present disclosure, will be described in detail with reference to the accompanying drawings.

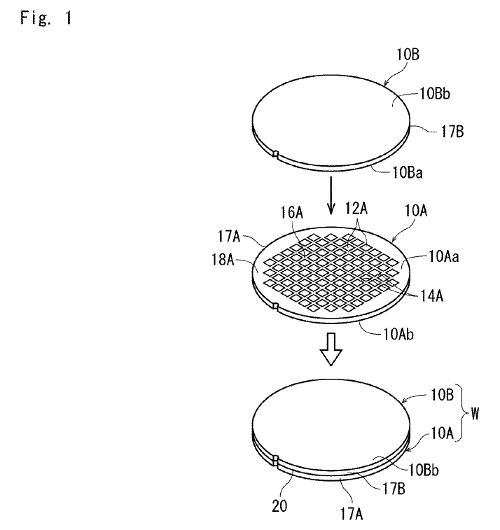

FIG. 1 illustrates an example of a bonded wafer W which is processed by the wafer processing apparatus and the wafer processing method of this embodiment. The illustrated bonded wafer W is a bonded wafer in which a first wafer 10A and a second wafer 10B are bonded and integrated. The first wafer 10A is a silicon (Si) wafer, for example, of which diameter is 300 mm and thickness is 775 μm, and a plurality of devices 12A are formed on a front face 10Aa, so as to be divided by the division lines 14A. The first wafer 10A has the front face 10Aa and a rear face 10Ab, and includes a device region 16A which is located at the center where the devices 12A, to be used as products, are formed, and an outer peripheral surplus region 18A, where the chamfered portion 17A is formed at the outer periphery, and which surrounds the device region 16A.

The second wafer 10B has a same configuration as the first wafer 10A, where a chamfered portion 17B is formed at the outer periphery, and although illustration is omitted, the second wafer 10B is also a silicon wafer, of which diameter is 300 mm and thickness is 775 μm, and a plurality of devices, corresponding to the devices 12A on the first wafer 10A, are formed on a front face 10Ba (disposed on the lower face side in FIG. 1), so as to be divided by the division lines. The width of the chamfered portion 17A (17B) that is formed is 0.6 to 6 mm, for example, and in this embodiment, the width of the chamfered portion 17A (17B) of the bonded wafer W is 5 mm.

The first wafer 10A and the second wafer 10B of the bonded wafer W of this embodiment are integrated, for example, by bonding the front face 10Aa of the first wafer 10A and the front face 10Ba of the second wafer 10B, forming an interface 20 by siloxane bonds. The siloxane bonds is a Si-O-Si bonds where silicon (Si) and oxygen (O) are bonded alternately, and the first wafer 10A and the second wafer 10B are thermally treated and bonded thereby. Hence a firm bonded state can be maintained even in a high temperature environment.

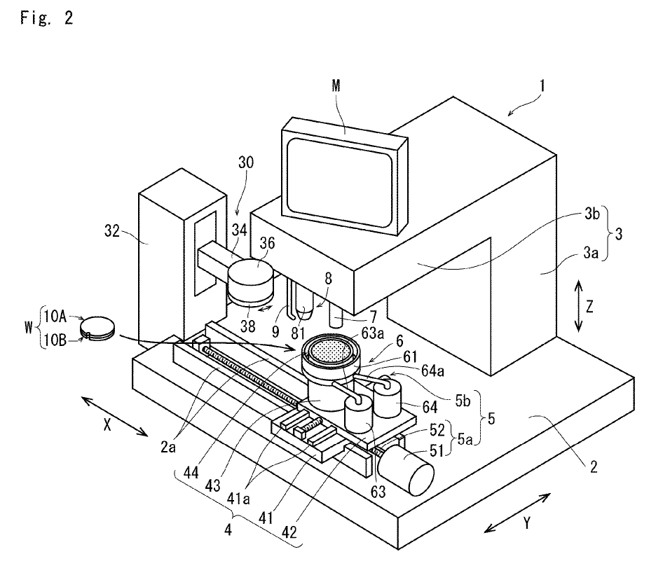

A laser processing apparatus 1 will be described with reference to FIG. 2, which is a wafer processing apparatus configured based on the present disclosure, and is a preferred example of a wafer processing apparatus to implement the wafer processing method of the present disclosure. The illustrated laser processing apparatus 1 includes: a holding table 44 which holds the second wafer 10B of the abovementioned bonded wafer W; a laser beam applying unit 8 which forms a ring-shaped modified layer by positioning a condensing point of a laser beam on an inner side adjacent to the chamfered portion 17A, formed at an outer periphery of the first wafer 10A of the bonded wafer W held on the holding table 44, and applying the laser beam; and a fluid supplying unit 6 that supplies fluid L to weaken a bonding force to an interface 20 of the chamfered portions 17A and 17B where the first wafer 10A and the second wafer 10B are bonded.

The laser processing apparatus 1 is installed on a base 2, and includes, in addition to the above configuration: a holding unit 4 which includes the holding table 44 to hold the bonded wafer W; a moving unit 5 which moves the holding unit 4; an imaging unit 7 which images the bonded wafer W held on the holding table 44 of the holding unit 4 and executes alignment; a frame 3 which is constituted of a vertical wall portion 3a, which is vertically disposed on the side of the moving unit 5, and a horizontal wall portion 3b which extends from the upper end of the vertical wall portion 3a in the horizontal direction; a display unit M which is installed on the frame 3; a chamfered portion removal unit 30 which removes the chamfered portion 17A from the outer periphery of the first wafer 10A where the modified layer is formed; and a control unit (not illustrated).

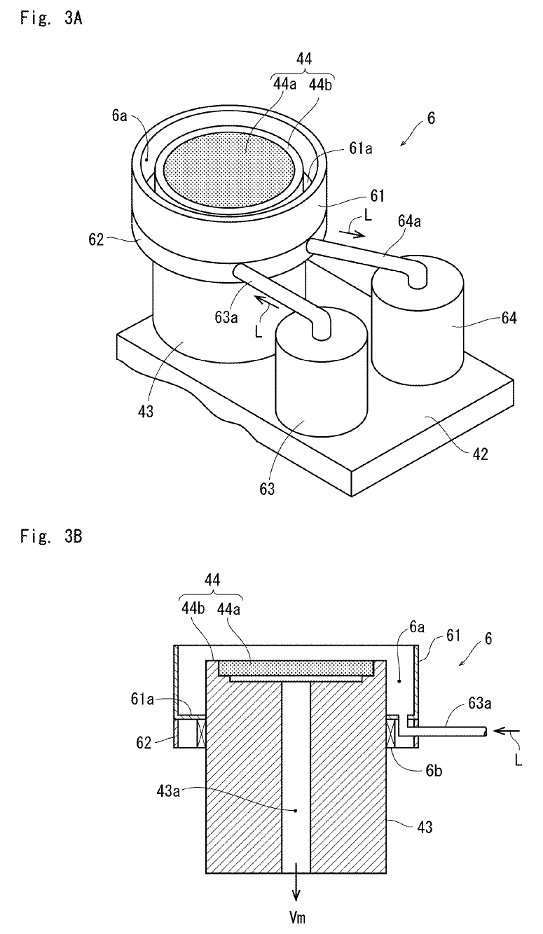

As illustrated in FIG. 2, the holding unit 4 includes: an X axis direction movable plate 41 which is a rectangular plate disposed on the base 2 to be movable in the X axis direction; a Y axis direction movable plate 42 which is a rectangular plate disposed on the X axis direction movable plate 41 to be movable in the Y axis direction; and a support 43 which is approximately cylindrical and is fixed to the upper face of the Y axis direction movable plate 42, and the holding table 44 is installed on the upper end of the support 43. As illustrated in FIG. 3A, the holding table 44 is constituted of a holding face 44a which is formed of a member having permeability, and a frame 44b which surrounds the holding face 44a and is connected to a suction unit (not illustrated). The holding table 44 is configured to be rotatable by a rotary driving unit (not illustrated). A liquid storage tank 61, which constitutes the later mentioned fluid supplying unit 6, is disposed on the holding table 44. The liquid storage tank 61 is configured to surround the holding table 44 such that the upper portion is open.

The moving unit 5 includes an X axis moving unit 5a which moves the holding unit 4 in the X axis direction, and a Y axis moving unit 5b which moves the holding unit 4 in the Y axis direction which orthogonally intersects the X axis direction. The X axis moving unit 5a converts a rotary motion of a motor 51 into a linear motion via a ball screw 52, and transfers the linear motion to the X axis direction movable plate 41, whereby the X axis direction movable plate 41 is moved in the X axis direction along a pair of guide rails 2a and 2a disposed on the base 2 in the X axis direction. The Y axis moving unit 5b is not illustrated in detail, but has the same configuration as the X axis moving unit 5a described above. That is, the Y axis moving unit 5b transfers the rotary motion of the motor to the Y ais direction movable plate 42, whereby the Y axis direction movable plate 42 is moved along a pair of guide rails 41a and 41a disposed on the X axis direction movable plate 41 in the Y axis direction.

An optical system constituting the abovementioned laser beam applying unit 8 is housed inside the horizontal wall portion 3b of the frame 3. A condenser 81 is disposed on the lower face side of the front end of the horizontal wall portion 3b. The condenser 81 is a part of the laser beam applying unit 8, and condenses a laser beam having a wavelength that is transmissive to at least the abovementioned first wafer 10A, and applies the laser beam onto the bonded wafer W. An imaging unit 7 is also disposed at a position adjacent to the condenser 81 in the X axis direction. The imaging unit 7 is a camera that images the bonded wafer W which is held on the holding table 44 of the holding unit 4, and detects a position and orientation of the bonded wafer W and a processing position onto which the laser beam is applied. In the illustrated embodiment, a fluid removal unit 9 is disposed adjacent to the condenser 81. The fluid removal unit 9 is a pipe-shaped member, and injects gas, which is supplied from a gas supplying unit (not illustrated), from the tip. The fluid removal unit 9 is disposed on the upper face of the bonded wafer W (rear face 10Ab of the first wafer 10A) to remove the fluid L from the position onto which the laser beam is applied. The functions and effects of the fluid removal unit 9 will be described later.

The liquid storage tank 61, constituting of the fluid supplying unit 6, is for dipping the chamfered portions 17A and 17B of the bonded wafer W into the fluid L stored in a storage portion 6a of the liquid storage tank 61, such that the upper face (rear face 10Ab) of the first wafer 10A is exposed out of the fluid L. As illustrated in FIG. 2 and FIG. 3A, which is an enlarged view of the fluid supplying unit 6, a fluid supplying pump 63, to supply the fluid L, to weaken the bonding force at the interface 20 of the chamfered portions 17A and 17B, to the storage portion 6a of the liquid storage tank 61, and a supplying pipe 63a, to guide the fluid L discharged from the fluid supplying pump 63 to the liquid storage tank 61, are disposed adjacent to the liquid storage tank 61. Further, a drain pump 64 to discharge the fluid L stored in the storage portion 6a of the liquid storage tank 61 to the outside, and a drain pipe 64a to discharge the fluid L from the liquid storage tank 61 via the drain pump 64, are disposed adjacent to the liquid storage tank 61. This fluid L contains at least one of water and ammonia, for example, or may be a mixed solution of water and ammonia.

The fluid supplying pump 63 and the drain pump 64 are disposed on the Y axis direction movable plate 42, and move, along with the support 43 and the holding table 44, in the X axis direction and the Y axis direction by activating the abovementioned moving unit 5. As illustrated in FIGS. 3A and 3B, an annular cover member 62 is disposed below the liquid storage tank 61, and the abovementioned supplying pipe 63a and the drain pipe 64a are connected to a bottom portion 61a of the liquid storage tank 61 via the cover member 62. The holding table 44 constituting the upper face of the support 43 is disposed so as to protrude upward from the center of the bottom portion 61a of the liquid storage tank 61, and an annular seal member 6b is disposed between the bottom portion 61a of the liquid storage tank 61 and the support 43. The holding table 44 is rotatably supported by a rotary-driving unit (not illustrated), which rotates around the liquid storage tank 61 which is fixed to the Y axis direction movable plate 42 by a fixing unit (not illustrated). By the presence of the abovementioned seal member 6b, the leaking of fluid L from the liquid storage tank 61 is prevented, even if the holding table 44 is rotated in a state where the fluid L is stored in the storage portion 61a of the liquid storage tank 61. As illustrated in FIG. 3B, a suction passage 43a, connected to a suction unit (not illustrated), is formed inside the support 43. By activating this suction unit, a negative pressure Vm can be generated on the holding face 44a of the holding table 44.

The laser processing apparatus 1 of this embodiment generally includes the abovementioned configuration, and the laser processing apparatus 1 performs a wafer processing method which will be described below. More specifically, the laser processing apparatus 1 performs laser processing to form a ring-shaped modified layer on the inner side adjacent to the chamfered portion 17A, which is formed at the outer periphery of the first wafer 10A of the bonded wafer W described above. The wafer processing method performed by the abovementioned configuration and the functional effects implemented by this embodiment will be described below.

To perform the wafer processing method of this embodiment, the abovementioned laser processing apparatus 1 is prepared (the preparing). The laser processing apparatus 1 is the abovementioned wafer processing apparatus that includes at least: the holding table 44; the laser beam applying unit 8; and the fluid supplying unit 6 that supplies fluid L to weaken a bonding force to the interface 20 of the chamfered portions 17A and 17B, where the first wafer 10A and the second wafer 10B constituting the bonded wafer W held on the holding table 44 are bonded. The fluid supplying unit 6 includes the liquid storage tank 61, on the outer periphery of the holding table 44, to dip the chamfered portions of the bonded wafer W such that the upper face of the first wafer 10A is exposed out of the fluid L.

After the laser processing apparatus 1 is prepared as mentioned above, the holding is performed. More specifically, the bonded wafer W is conveyed to the laser processing apparatus 1 described with reference to FIG. 1, using a conveying unit (not illustrated), and the second wafer 10B of the bonded wafer W is held on the holding table 44. Specifically, the bonded wafer W, conveyed to the laser processing apparatus 1, is placed on the abovementioned holding table 44 such that the second wafer 10B is on the inner side and the rear face 10Ab of the first wafer 10A faces up, and a suction unit (not illustrated) is activated to hold the bonded wafer W by suction on the holding table 44. A protective tape may be attached (not illustrated) to the rear face 10Bb side of the second wafer 10B, which is positioned on the lower side when the bonded wafer W is placed on the holding table 44. If this protective tape is attached, suction of the fluid L from the holding face 44a of the holding table 44 can be prevented, even if the fluid L is stored in the liquid storage tank 61 to dip the bonded wafer W.

Then alignment is performed using the imaging unit 7 disposed in the laser processing apparatus 1. By this alignment, the bonded wafer W is imaged and the position of the edge of the outer periphery, at which the chamfered portion 17A of the first wafer 10A is formed, and the height of the upper face of the rear face 10Ab of the first wafer 10A, are detected. Then in the region corresponding to the outer peripheral surplus region 18A on an inner side adjacent to the chamfered portion 17A, which is formed at the outer periphery of the first wafer 10A, a processing position, at which the condensing point of the laser beam LB is positioned and onto which the laser beam LB is applied (a position at a 145 mm radius from the center of the first wafer 10A if the diameter of the bonded wafer W is 300 mm), is detected.

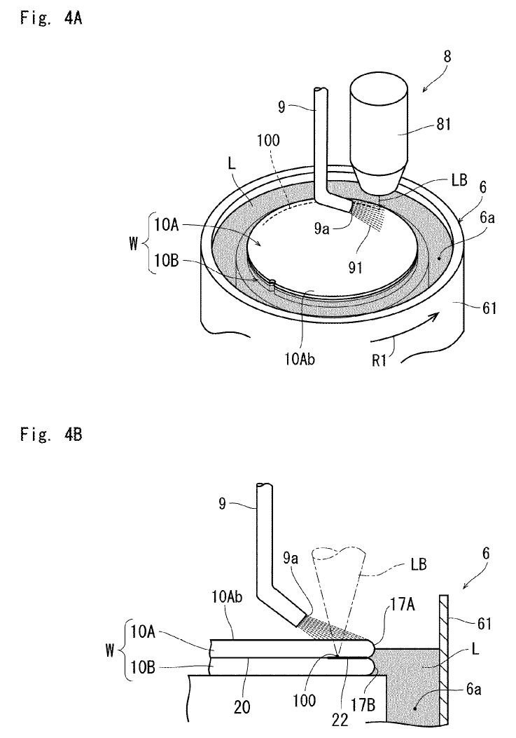

After performing the abovementioned alignment, the fluid supplying unit 6 performs the supplying of the fluid, in which the fluid L to weaken the bonding force is supplied to the interface 20 of the chamfered portions 17A and 18B, where the first wafer 10A and the second wafer 10B of the bonded wafer W, held on the holding table 44, are bonded. Specifically, the fluid supplying pump 63 of the fluid supplying unit 6 is activated, and a predetermined amount of the fluid L is supplied to the storage portion 6a of the liquid storage tank 61 via the supplying pipe 63a, as illustrated in FIG. 4A. Here the drain pump 64 is stopped, hence the fluid L is not drained through the drain pipe 64a. The predetermined amount of fluid L refers to an amount of fluid in which the chamfered portions 17A and 17B of the bonded wafer W, held on the holding table 44, is dipped, such that the upper face of the bonded wafer W, that is, the rear face 10Ab of the first wafer 10A, is exposed upward out of the fluid L, as illustrated in FIG. 4B. Thereby the fluid L, to weaken the bonding force is supplied to the outer periphery of the interface 20 of the bonded wafer W.

In the interface 20 of this embodiment, the first wafer 10A and the second wafer 10B are bonded by the siloxane bonds (Si-O-Si bonds). When the fluid L is supplied to the interface 20 from the side, water molecules gradually infiltrate into the interface 20, and the region where the water molecules entered changes to the Si-OH-OH-Si bonds. In this way, the bonding force of the interface 20 is weakened by performing the supplying of the fluid, and an annular low-bonding force region 22, where a bonding force is lower than the siloxane bonds, is formed at the outer periphery of the interface 20 of the bonded wafer W, as illustrated in FIG. 4B. In the above description, the fluid supplying pump 63 of the fluid supplying unit 6 is activated, and the fluid L is supplied to the liquid storage tank 61 after performing the alignment, but the fluid L may be supplied to the liquid storage tank 61, and the fluid L to weaken the bonding force may be supplied to the interface 20 of the chamfered portion 17A and the chamfered portion 17B, where the first wafer 10A and the second wafer 10B are bonded, before performing the alignment, or at the same timing of performing the alignment. In the case of supplying the fluid L to the interface 20 of the bonded wafer W, the low-bonding force region 22 may be formed first by supplying an amount of fluid L, sufficient enough to dip the entire bonded wafer W, to the liquid storage tank 61, and then the drain pump 64 may be activated to drain the fluid L from the liquid storage tank 61, so that at least the rear face 10Ab of the first wafer 10A is exposed.

As described above, if the low-bonding force region 22 is formed at the interface 20 of the bonded wafer W by supplying the fluid L to the interface 20 of the bonded wafer W, the forming of the modified layer is performed to form a ring-shaped modified layer, by positioning, with the use of the abovementioned laser beam applying unit 8, the condensing point of the laser beam at the outer peripheral surplus region 18A, which is an inner side adjacent to the chamfered portion 17A formed on an outer periphery of the first wafer 10A of the bonded wafer W held on the holding table 44, and on which the devices 12A are not formed, thereafter applying the laser beam, as described later.

In a case of forming the modified layer for the first wafer 10A of the bonded wafer W in the forming of the modified layer, the laser processing is performed based on the position information on the processing position (e.g. a position on a 145 mm radius from the center point of the first wafer 10A) detected by the abovementioned alignment.

First the moving unit 5 is activated based on the position information on the processing position detected by the abovementioned alignment, so as to move the holding table 44, and then the processing position, which is set on the first wafer 10A of the bonded wafer W, is positioned immediately below the condenser 81 of the laser beam applying unit 8, as illustrated in FIG. 4A. Then as illustrated in FIGS. 4A and 4B, the laser beam applying unit 8 is activated, so that the condensing point of the laser beam LB, which has a wavelength that is transmissive to the first wafer 10A, is positioned on the inner side of the processing position on the first wafer 10A, and thereafter applies the laser beam LB from the rear face 10Ab side of the first wafer 10A. At the same time, the holding table 44 is rotated in the arrow R1 direction indicated in FIG. 4A, so as to form a ring-shaped modified layer 100 along the inner side of the chamfered portion 17A of the first wafer 10A.

In the case of forming the modified layer 100 by activating the laser beam applying unit 8 and applying the laser beam LB as mentioned above, gas 91 is injected from the tip 9a of the fluid removal unit 9 by activating the fluid removal unit 9, as illustrated in FIGS. 4A and 4B. Thereby fluid L, which adhered to the region onto which the laser beam LB is applied, (the outer periphery onto which the laser beam LB is applied), is removed from the upper face of the first wafer 10A. This prevents the fluid L from interrupting the laser processing to form the modified layer 100. The gas injected from the fluid removal unit 9 is typically air, but a fluid having high volatility may be injected from the fluid removal unit 9, so as to generate gas on the upper surface of the bonded wafer W. This fluid having high volatility is liquid nitrogen or ammonia, for example.

It is preferable to form the modified layer 100 of this embodiment to have a plurality of layers in the vertical direction. For example, in the case of the modified layer 100 illustrated in FIG. 4B, the condensing point of the laser beam LB is positioned at a position which is set, such that the modified layer is formed inside the first wafer 10A on the inner side adjacent to the chamfered portion 17A, at a 650 μm depth from the rear face 10Ab near the interface 20, and the laser beam LB is applied onto the position, and at the same time, the holding table 44 is rotated to form the first layer of the ring-shaped modified layer along the chamfered portion 17A. Then while rotating the chuck table 34, the depth of the condensing point from the rear face 10Ab is raised three times: 500 μm --> 350 μm --> 200 μm, so that a total of four layers of ring-shaped modified layers (not illustrated) are formed in the vertical direction, along the chamfered portion 17A. A number of layers of the modified layer 100 formed by the laser beam applying unit 8 is not limited to four, as mentioned above, but may be appropriately set depending on the thickness of the first wafer 10A, the material of the first wafer 10A, the wavelength and output of the laser beam LB that is applied by the laser beam applying unit 8, and the like. The wafer processing method of this embodiment is completed thereby.

In this embodiment illustrated above, the laser processing is performed in the state where the fluid L is stored in the liquid storage tank 61, but the present disclosure is not always limited to performing the laser processing in the state where the fluid L is stored in the liquid storage tank 61. For example, if the fluid L stored in the liquid storage tank 61 is supplied to the interface 20 of the bonded wafer W, and is sufficiently wide low-bonding force region 22 is formed thereby before forming the abovementioned modified layer 100, then the drain pump 64 may be activated, and the fluid L may be drained from the liquid storage tank 61 via the drain pipe 64a before the laser beam applying unit 8 forms the modified layer 100.

The laser processing conditions to form the abovementioned modified layer 100 are set as follows, for example.

Wavelength: 1099 nm or 1342 nm

Repetition frequency: 80 kHz

Average output power: 2.0 W

Holding table rotation speed: 60 rpm

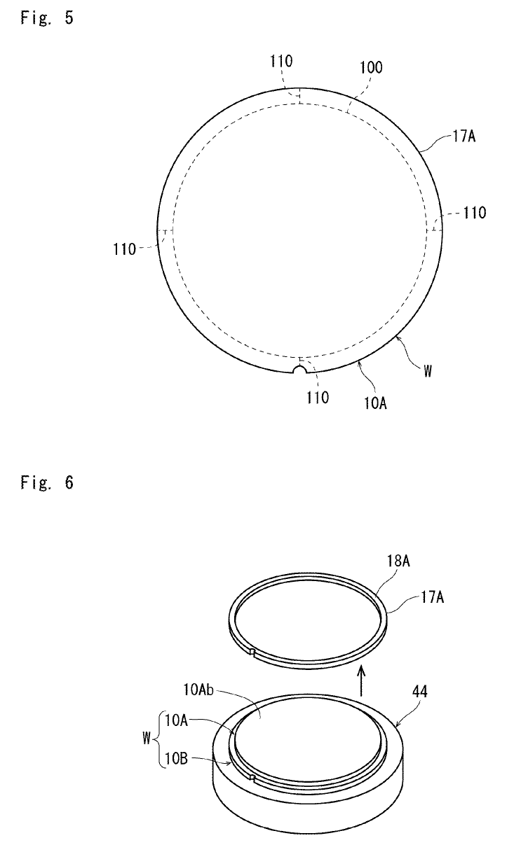

In the abovementioned forming of the modified layer, in addition to the modified layer 100, radial modified layers 110 may be formed, as illustrated in FIG. 5. The modified layers extend from the region, where the modified layer 100 is formed in the direction toward the outer edge where the chamfered portion 17A is formed. The modified layer 110 is formed, by applying the laser beam LB under the same laser processing conditions as the case of forming the modified layer 100 mentioned above, and is formed at a plurality of locations at equal intervals (four locations in the illustrated example of this embodiment) at the outer periphery of the first wafer 10A. By forming these modified layers 110, the chamfered portions 17A are finely separated when the chamfered portion 17A is removed from the first wafer 10A, and the chamfered portion 17A can be removed more easily.

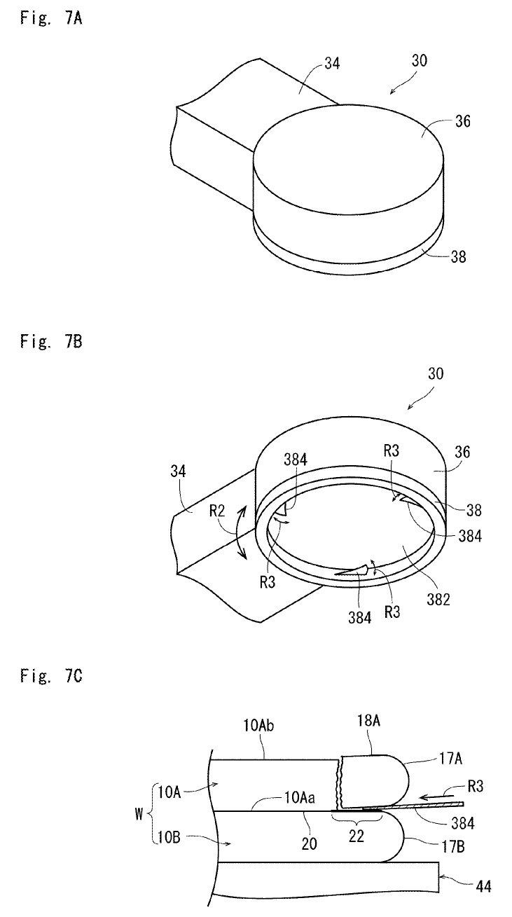

As mentioned above, after forming the modified layer 100 at the outer periphery of the first wafer 10A, the removing of the chamfered portion is performed, where the chamfered portion 17A, including the outer peripheral surplus region 18A, is removed from the outer periphery of the first wafer 10A on which the modified layer 100 is formed, as illustrated in FIG. 6, by applying external force to the bonded wafer W. In this embodiment, the modified layer 100 is formed on the first wafer 10A, hence the outer peripheral surplus region 18A, including the chamfered portion 17A, can easily be removed by simply applying external force. The laser processing apparatus 1 of this embodiment includes the chamfered portion removal unit 30, as illustrated in FIGS. 2 and 7A to 7C, and can remove the chamfered portion 17A by the chamfered portion removal unit 30.

As illustrated in FIG. 2, the chamfered portion removal unit 30 includes: a casing 32 which extends upward from the edges of the guide rails 2a and 2a on the base 2; and an arm 34 which is elevatably supported by the casing 32 and extends in the X axis direction. The casing 32 includes an elevating unit (not illustrated) which moves the arm 34 up and down. At the front end of the arm 34, a motor 36 is disposed, and the chamfered portion removing portion 38 is connected to the lower face of the motor 36 so as to be rotary-driven by the motor 36 around the shaft line, which extends in the vertical direction.

FIG. 7A is an enlarged view of the motor 36 and a chamfered portion removing portion 38 of the chamfered portion removal unit 30, and FIG. 7B is a view of the chamfered portion removing portion 38 viewed obliquely from the lower side, as illustrated in FIG. 7A. As illustrated in FIG. 7B, the chamfered portion removing portion 38 is configured to be ring-shaped, and a plurality of blades 384, to remove the abovementioned chamfered portion 17A of the first wafer 10A, are disposed on the inner side face of this ring-shaped chamfered portion removing portion 38. These blades 384 are thin razor-like blades, and protrude in the inner direction as indicated by the arrows R3 in FIGS. 7B and 7C, or are housed inside the chamfered portion removing portion 38, by the chamfered portion removing portion 38 that is driven and rotated forward or backward, by the motor 36 as indicated by the arrow R2 in FIG. 7B.

As described above, the modified layers 100 and 110 are formed in the outer peripheral surplus region 18A of the first wafer 10A, and then to remove the chamfered portion 17A, the X axis moving unit 5a and the Y axis moving unit 5b are activated, so as to position the holding table 44 below the chamfered portion removing portion 38. Then the abovementioned arm 34 is lowered such that the lower face 382 of the chamfered portion removing portion 38, illustrated in FIG. 7B, is contacted with the rear face 10Ab of the first wafer 10A of the bonded wafer W. Then the chamfered portion removing portion 38 is activated using the motor 36 of the chamfered portion removal unit 30, so that the abovementioned blades 384 protrude inward, as indicated by the arrow R3 in FIG. 7C. Thereby the blades 384 can enter the low-bonding force region 22 formed at the interface 20 of the bonded wafer W, and the outer peripheral surplus region 18A, including the chamfered portion 17A, can be broken off, starting from the abovementioned modified layer 100, by rotating the holding table 44.

After breaking off the outer peripheral surplus region 18A, including the chamfered portion 17A, the abovementioned motor 36 is activated so as to house the blades 384 in the chamfered portion removing portion 38, and the motor 36 elevates the arm 34 of the chamfered portion removal unit 30. Thereby the removal of the chamfered portion 17A from the first wafer 10A of the bonded wafer W is completed.

As mentioned above, once the chamfered portion 17A is removed from the first wafer 10A of the bonded wafer W, grinding is performed if necessary, to grind the rear face 10Ab of the first wafer 10A, so that the bonded wafer W has the desired thickness.

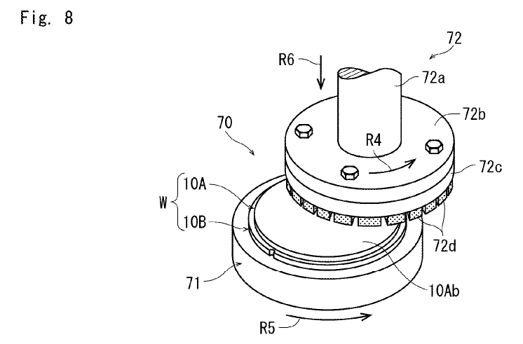

In the case of performing grinding, the abovementioned bonded wafer W, after removing the chamfered portion 17A, is conveyed to a grinding apparatus 70 (of which a part is illustrated) in FIG. 8. As illustrated in FIG. 8, the grinding apparatus 70 includes a grinding unit 72 which grinds and thins the bonded wafer W held on a chuck table 71 by suction. The grinding unit 72 includes: a rotation spindle 72a which is rotated by a rotary-driven mechanism (not illustrated); a wheel mount 72b which is attached to the bottom end of the rotation spindle 72a; and a grind wheel 72c which is attached to the lower face of the wheel mount 72b. A plurality of grinding stones 72d are disposed in a ring shape on the lower face of the grind wheel 72c.

When the bonded wafer W, conveyed to the grinding apparatus 70, is placed on the chuck table 71 with the second wafer 10B side down, as illustrated in FIG. 8, it is held thereon by suction using a suction unit (not illustrated). Then while rotating the rotation spindle 72a of the grinding unit 72 at 6000 rpm, for example, in the arrow R4 direction, as indicated in FIG. 8, the chuck table 71 is rotated at 300 rpm, for example, in the arrow R5 direction. Then while supplying grinding water onto the rear face 10Ab of the first wafer 10A using a grinding water supplying unit (not illustrated), the grinding stones 72d are contacted with the rear face 10Ab of the first wafer 10A by activating a grinding feed unit (not illustrated), and the grind wheel 72c is operated for grinding downward in the arrow R6 direction at a 1.0 μm/sec. grinding feed speed, for example. Here the grinding is advanced while measuring the thickness of the bonded wafer W using a contact type or non-contact type measuring gauge (not illustrated), so as to thin the bonded wafer W to a desired thickness.

When a predetermined amount of grinding is performed from the rear face 10Ab of the first wafer 10A and a desired thickness of the bonded wafer W is implemented, the grinding unit 72 is retracted upward, and the grinding is completed. Once the grinding is completed, cleaning and drying processing and the like (details omitted here) are performed, whereby the wafer processing of this embodiment is completed.

According to the embodiment described above, the bonding force in the regions corresponding to the abovementioned chamfered portions 17A and 17B at the interface 20 of the bonded wafer W, which is bonded in advance by the siloxane bonds, is weakened. Therefore the chamfered portion 17A of the first wafer 10A can be easily removed, starting from the modified layer 100 formed in a ring shape, and the problem of the difficulty in removing the chamfered portion 17A is solved. Further, it is not necessary to remove the chamfered portion 17A using a cutting blade, that is, the problem of scratching the second wafer 10B, to which the first wafer 10A is bonded, is also solved.

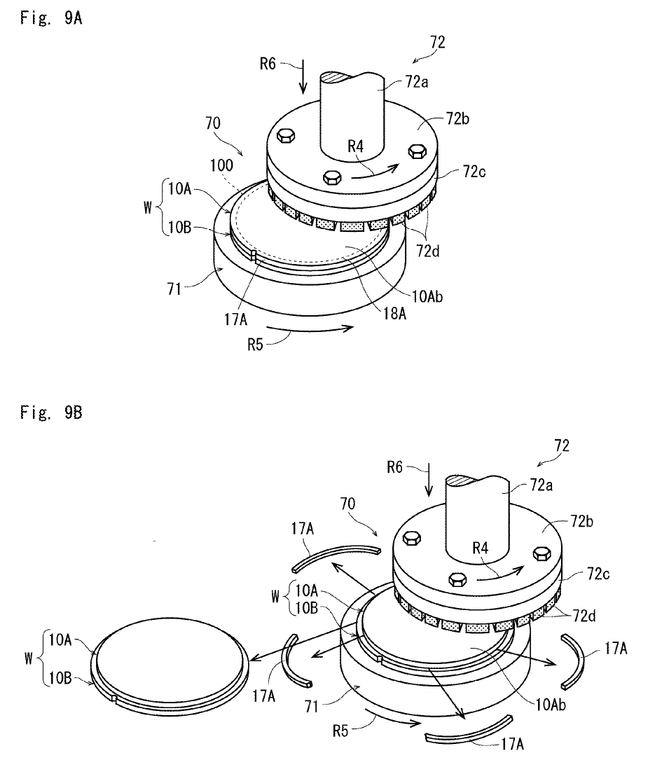

The present disclosure is not limited to the above embodiment. In the laser processing apparatus 1 of the above embodiment, the chamfered portion removal unit 30 is disposed, but this chamfered portion removal unit 30 may not be included in the laser processing apparatus 1. In the case of not including the chamfered portion removal unit 30, the removing of a chamfered portion, in which the chamfered portion 17A is removed by grinding, may be performed. Specifically, after forming the abovementioned modified layer 100 on the first wafer 10A of the bonded wafer W, the bonded wafer W is conveyed to the abovementioned grinding apparatus 70, as illustrated in FIG. 9A, and is held on the chuck table 71 by suction with the second wafer 10B side facing down and the rear face 10Ab of the first wafer 10A facing up.

Then while rotating the rotation spindle 72a of the grinding unit 72 at 6000 rpm, for example, in the arrow R4 direction, indicated in FIG. 9A, the chuck table 71 is rotated at 300 rpm, for example, in the arrow R5 direction. Then while supplying grinding water onto the rear face 10Ab of the first wafer 10A using a grinding water supplying unit (not illustrated), the grinding stones 72d are contacted with the rear face 10Ab of the first wafer 10A by activating the grinding feed unit (not illustrated), and the grind wheel 72c is operated for grinding downward in the arrow R6 direction at a 1.0 μm/sec. grinding feed speed, for example. Thereby an external force is applied to the rear face 10Ab of the first wafer 10A, and the outer peripheral surplus region 18A, including the chamfered portion 17A, is removed, starting from the modified layer 100. Here it is preferable that the radial modified layers 110 have been formed, as mentioned above, so that the chamfered portion 17A is appropriately divided at the outer periphery, starting from the radial modified layers 110, and is removed from the first wafer 10A favorably. In the case of grinding the rear face 10Ab of the first wafer 10A of the bonded wafer W using the grinding apparatus 70, rough grinding is performed first using grinding stones for rough grinding, which are appropriate for rough grinding, and the chamfered portion 17A is removed starting from the modified layers 100 and 110, and the rough grinding is continued until the bonded wafer W reaches a predetermined thickness. Then finish grinding is performed on the rear face 10Ab of the first wafer 10A using grinding stones for finish grinding, which are appropriate for finish grinding.

As described above, when a predetermined amount of grinding of the rear face 10Ab of the first wafer 10A is performed and the bonded wafer W reaches a predetermined thickness, the grinding unit 72 is stopped and retracted upward. Thereby the grinding is completed, and the bonded wafer W, having a predetermined thickness, from which the chamfered portion 17A has been removed, can be obtained, as illustrated in the lower left of FIG. 9B. Once the grinding is completed, cleaning and drying processing and the like (details omitted here) are performed. In this way, just like the abovementioned embodiment, the chamfered portion 17A of the first wafer 10A can be easily removed, starting from the modified layer 100 formed in a ring shape using the grinding apparatus 70, and the problem of the difficulty in removing the chamfered portion 17A is solved. Further, it is not necessary to remove the chamfered portion 17A using a cutting blade, that is, the problem of scratching the second wafer 10B, to which the first wafer 10A is bonded, is also solved.

In the bonded wafer W described above, the first wafer 10A and the second wafer 10B are bonded by the siloxane bonds, but the bonded wafer processed by the processing apparatus of the present disclosure is not limited to the wafer bonded by the siloxane bonds. For example, the bonded wafer may be formed by bonding the first wafer 10A and the second wafer 10B by a SiCN bond (nitride bond), or by a TEOS bond, in which tetraethyl orthosilicate molecules are transformed to have an Si-O-Si bonds, or by a ThOx bond based on silicon oxide film (SiO₂) formed by oxidizing the surface of the silicon wafer by heating in an oxygen atmosphere. The bonding force can be weakened by the abovementioned fluid L, regardless what bonding is used. The wafer processing apparatus and the wafer processing method of the present disclosure are applicable also to the bonded wafer W bonded by performing O₂ plasma treatment or N₂ plasma treatment as a pretreatment of the bonding surface on which the interface 20 is formed.

### Reference Signs List

1 Laser processing apparatus

2 Base

3 Frame

4 Holding unit

41 X axis direction movable plate

42 Y axis direction movable plate

43 Support

44 Holding table

44a Holding surface

44b Frame

5 Moving unit

5a X axis moving unit

5b Y axis moving unit

6 Fluid supplying unit

61 Liquid storage tank

62 Cover member

63 Fluid supplying pump

64 Drain pump

7 Imaging unit

8 Laser beam applying unit

81 Condenser

9 Fluid removal unit

10A First wafer

10Aa Front face

10Ab Rear face

12A Device

14A Division line

16A Device region

17A Chamfered portion

18A Outer peripheral surplus region

10B Second wafer

17B Chamfered portion

20 Interface

22 Low bonding force region

30 Chamfered portion removal unit

32 Casing

34 Arm

36 Motor

38 Chamfered portion removing portion

382 Lower face

384 Blade

70 Grinding apparatus

71 Chuck table

72 Grinding unit

72d Grinding stones

What is claimed is:

1. A wafer processing apparatus performing processing on a bonded wafer in which a first wafer and a second wafer are bonded, the wafer processing apparatus comprising:
a holding table configured to hold the second wafer of the bonded wafer;
a laser beam applying unit configured to form a ring-shaped modified layer by positioning a condensing point of a laser beam on an inner side adjacent to a chamfered portion, which is formed at an outer periphery of the first wafer of the bonded wafer held on the holding table, and applying the laser beam; and
a fluid supplying unit configured to supply fluid weakening a bonding force to an interface of the chamfered portion in which the first wafer and the second wafer are bonded, wherein
the fluid supplying unit includes a liquid storage tank, into which the chamfered portion of the bonded wafer is dropped, at an outer periphery of the holding table, such that an upper face of the first wafer is exposed out of the fluid.

2. The wafer processing apparatus of claim 1, wherein
in a case of applying the laser beam in a state
where the chamfered portion of the bonded wafer is dipped in the liquid storage tank of the fluid supplying unit and the upper face of the first wafer is exposed out of the fluid, a fluid removal unit configured to remove the fluid adhering to the upper face of the first wafer is disposed.

3. The wafer processing apparatus of claim 1, wherein
the fluid removal unit removes the fluid from the upper face of the first wafer by injecting gas from a nozzle to an applying position of the laser beam.

4. The wafer processing apparatus of claim 1, wherein
a chamfered portion removal unit configured to remove the chamfered portion from the outer periphery of the first wafer in which the modified layer is formed is disposed.

5. The wafer processing apparatus of claim 1, wherein
the first wafer and the second wafer are bonded by siloxane bonds of Si-O-Si,
the fluid to weaken the bonding force contains at least one of water and ammonia, and
the bonding force at the interface is weakened by the function of the fluid, with the bonding of Si-O-Si changing into bonding of Si-OH-OH-Si.

6. A wafer processing method to perform processing on a bonded wafer in which a first wafer and a second wafer are bonded, the method comprising:
preparing the wafer processing apparatus of claim 1;
holding the second wafer of the bonded wafer on a holding table of the wafer processing apparatus;
supplying fluid weakening a bonding force to an interface of a chamfered portion, in which the first wafer and the second wafer are bonded, of the bonded wafer held on the holding table by using a fluid supplying unit of the wafer processing apparatus; and
forming a ring-shaped modified layer by positioning a condensing point of a laser beam on an inner side adjacent to a chamfered portion formed on an outer periphery of the first wafer of the bonded wafer held on the holding table, and applying the laser beam, wherein
in the supplying fluid, the chamfered portion of the bonded wafer is dipped into a liquid storage tank disposed at the outer periphery of the holding table such that the fluid weakening the bonding force at the interface of the chamfered portion is supplied and an upper face of the first wafer is exposed out of the fluid.
